(19) United States
(12) Patent Application Publication
(10) Pub. No.: US 2024/0419037 A1
(43) Pub. Date: Dec. 19, 2024

(54) DISPLAY PANELS AND DISPLAY DEVICES

(71) Applicant: GUANGZHOU CHINA STAR OPTOELECTRONICS SEMICONDUCTOR DISPLAY TECHNOLOGY CO., LTD., Guangzhou (CN)

(72) Inventor: Qingjuan WANG, Guangzhou (CN)

(21) Appl. No.: 18/266,788

(22) PCT Filed: Apr. 21, 2023
(86) PCT No.: PCT/CN2023/089660

§ 371 Date: Jun. 12, 2023

(30) Foreign Application Priority Data
Mar. 30, 2023 (CN) 202310332091.8

(51) Int. Cl. G02F 1/1339; G02F 1/1333; G02F 1/1362; H01L 27/12

(52) U.S. Cl. CPC G02F 1/13394; G02F 1/133357; G02F 1/136286; H01L 27/124

(57) ABSTRACT

A display panel and a display device are provided. the display panel includes an array substrate and an opposite substrate arranged opposite to each other. A plurality of spacers are provided on a side of the opposite substrate adjacent to the array substrate, and a plurality of dams are provided on a side of the array substrate adjacent to the opposite substrate to prevent ends of the spacers adjacent to the array substrate from sliding, thereby preventing the spacers from scratching an alignment layer on a surface of the array substrate.

### TECHNICAL FIELD

The present disclosure relates to the field of display technologies, and in particular, to display panels and display devices.

### BACKGROUND

Liquid Crystal Display (LCD) technology has advantage of high image quality, power saving, thin body, and various applications, so it is widely used in various consumer electronics products such as mobile phones, TVs, personal digital assistants, digital cameras, notebook computers, desktop computers, and so on.

Liquid crystal display panel mainly includes an array substrate and an opposite substrate opposite to each other, and includes a liquid crystal layer arranged between the array substrate and the opposite substrate. Spacers (PS) are provided on a side of the opposite substrate adjacent to the array substrate, and the spacers are configured to maintain a thickness of a gap between the array substrate and the opposite substrate, thereby preventing the liquid crystal layer from being squeezed and deformed to cause abnormal image display.

### SUMMARY OF THE INVENTION

### Technical Problems

When an existing liquid crystal display panel is squeezed or dropped, an end of the spacer close to the array substrate is prone to slide, and an alignment layer on a surface of the array substrate is easily scratched during the sliding process, resulting in display problems of light leakage and red and blue spots. Therefore, it is necessary to provide display panels and display devices to relieve the problems.

### Technical Solutions

Embodiments of the present disclosure provide display panels and display devices, which can prevent sliding of spacers and prevent the spacers from scratching an alignment layer on a surface of an array substrate.

Embodiments of the present disclosure provide a display panel, including an array substrate and an opposite substrate arranged opposite to each other, a plurality of spacers are provided on a side of the opposite substrate adjacent to the array substrate;
herein, a plurality of dams are provided on a side of the array substrate adjacent to the opposite substrate, and the dams are arranged around ends of the spacers adjacent to the array substrate.

According to an embodiment of the present disclosure, the dams are distributed along circumferential directions of the ends of the spacers adjacent to the array substrate and partially surround each of the spacers.

According to an embodiment of the present disclosure, a minimum distance between each of the dams and the opposite substrate is less than a height of each of the spacers.

According to an embodiment of the present disclosure, the array substrate includes a first base, an inorganic insulation layer, and buffer blocks disposed between the first base and the inorganic insulation layer, and each of the dams is at least composed of one of the buffer blocks and the inorganic insulation layer located on the one of the buffer blocks.

According to an embodiment of the present disclosure, the array substrate includes a first metal layer and a second metal layer, the first metal layer is disposed between the second metal layer and the first base, the first metal layer includes gates, and the second metal layer includes sources and drains;
herein, the buffer blocks are arranged in a same layer as the second metal layer and independently separated from the sources and the drains.

According to an embodiment of the present disclosure, in a direction perpendicular to the first base, each of the buffer blocks at least partially overlaps with the first metal layer, and each of the spacers overlaps with the first metal layer.

According to an embodiment of the present disclosure, in the direction perpendicular to the first base, each of the spacers does not overlap with the second metal layer, and each of the spacers does not overlap with the buffer blocks.

According to an embodiment of the present disclosure, the array substrate includes a first metal layer and a second metal layer, the first metal layer is disposed between the second metal layer and the first base, the first metal layer includes gates, and the second metal layer includes sources and drains; and
herein, the buffer blocks are arranged on a side of the second metal layer away from the first base.

According to an embodiment of the present disclosure, the array substrate includes a planarization layer disposed on the side of the second metal layer away from the first base, and the buffer blocks are disposed on a side of the planarization layer away from the first base.

According to an embodiment of the present disclosure, an orthographic projection of each of the buffer blocks on the first base is shaped as a rectangle, a square, a circle, or an oval.

Embodiments of the present disclosure further provide a display device, including a display device including an array substrate and an opposite substrate arranged opposite to each other, a plurality of spacers are provided on a side of the opposite substrate adjacent to the array substrate;
herein, a plurality of dams are provided on a side of the array substrate adjacent to the opposite substrate, and the dams are arranged around ends of the spacers adjacent to the array substrate.

According to an embodiment of the present disclosure, the dams are distributed along circumferential directions of the ends of the spacers adjacent to the array substrate and partially surround each of the spacers.

According to an embodiment of the present disclosure, a minimum distance between each of the dams and the opposite substrate is less than a height of each of the spacers.

According to an embodiment of the present disclosure, the array substrate includes a first base, an inorganic insulation layer, and buffer blocks disposed between the first base and the inorganic insulation layer, and each of the dams is at least composed of one of the buffer blocks and the inorganic insulation layer located on the one of the buffer blocks.

According to an embodiment of the present disclosure, the array substrate includes a first metal layer and a second metal layer, the first metal layer is disposed between the second metal layer and the first base, the first metal layer includes gates, and the second metal layer includes sources and drains;
herein, the buffer blocks are arranged in a same layer as the second metal layer and independently separated from the sources and the drains.

According to an embodiment of the present disclosure, in a direction perpendicular to the first base, each of the buffer blocks at least partially overlaps with the first metal layer, and each of the spacers overlaps with the first metal layer.

According to an embodiment of the present disclosure, in the direction perpendicular to the first base, each of the spacers does not overlap with the second metal layer, and each of the spacers does not overlap with the buffer blocks.

According to an embodiment of the present disclosure, the array substrate includes a first metal layer and a second metal layer, the first metal layer is disposed between the second metal layer and the first base, the first metal layer includes gates, and the second metal layer includes sources and drains; and
herein, the buffer blocks are arranged on a side of the second metal layer away from the first base.

According to an embodiment of the present disclosure, the array substrate includes a planarization layer disposed on the side of the second metal layer away from the first base, and the buffer blocks are disposed on a side of the planarization layer away from the first base.

According to an embodiment of the present disclosure, an orthographic projection of each of the buffer blocks on the first base is shaped as a rectangle, a square, a circle, or an oval.

### Beneficial Effects

Beneficial effects of the embodiments of the present disclosure are: display panels and display devices are provided according to the embodiments of the present disclosure, the display panel includes the array substrate and the opposite substrate arranged opposite to each other, and a plurality of spacers are provided on a side of the array substrate adjacent to the opposite substrate. Since the plurality of dams are provided on the side of the array substrate adjacent to the opposite substrate, and the dams are arranged around ends of the spacers adjacent to the array substrate, the dams can prevent sliding of the ends of the spacers adjacent to the array substrate, thereby preventing the spacers from scratching the alignment layer on the surface of the array substrate, and thus avoiding abnormal display problems of light leakage and red and blue spots on the display panel.

### DESCRIPTION OF DRAWINGS

In order to more clearly illustrate the technical solutions in the embodiments or in the related art, the drawings that need to be used in the description of the embodiments or the related art will be briefly introduced below. Obviously, the drawings in the following description are only some embodiments of the present disclosure. For those skilled in the art, other drawings can also be obtained based on these drawings without any creative effort.

FIG. 1 is a partial schematic view of a display panel according to a first embodiment of the present disclosure.

FIG. 2 is a sectional view of the display panel in the first embodiment along a direction A-A′ in FIG. 1.

FIG. 3 is a sectional view of the display panel in the first embodiment along a direction B-B′ in FIG. 1.

FIG. 4 is a partial schematic view of a display panel according to a second embodiment of the present disclosure.

FIG. 5 is a sectional view of the display panel in the second embodiment along a direction C-C′ in FIG. 4.

### EMBODIMENTS OF THE INVENTION

Following description of each embodiment refers to additional illustrations to illustrate specific embodiments of the present disclosure that can be implemented. Orientational terms mentioned in the present disclosure, such as “upper”, “lower”, “front”, “rear”, “left”, “right”, “inner”, “outer”, “side”, etc., merely refer to directions referring to the attached drawings. Therefore, the orientational terms are used to illustrate and understand the present disclosure, not to limit the present disclosure. In the figures, units with similar structures are indicated by same reference numerals.

The following is a further explanation of the present disclosure in conjunction with the accompanying drawings and specific embodiments.

Display panels are provided according to embodiments of the present disclosure. The display panel includes an array substrate and an opposite substrate arranged opposite to each other, and a plurality of spacers are provided on a side of the array substrate adjacent to the opposite substrate. Since a plurality of dams are provided on the side of the array substrate adjacent to the opposite substrate, and the dams are arranged around ends of the spacers adjacent to the array substrate, the dams can prevent sliding of the ends of the spacers adjacent to the array substrate, thereby preventing the spacers from scratching an alignment layer on a surface of the array substrate, and thus avoiding abnormal display problems of light leakage and red and blue spots on the display panel.

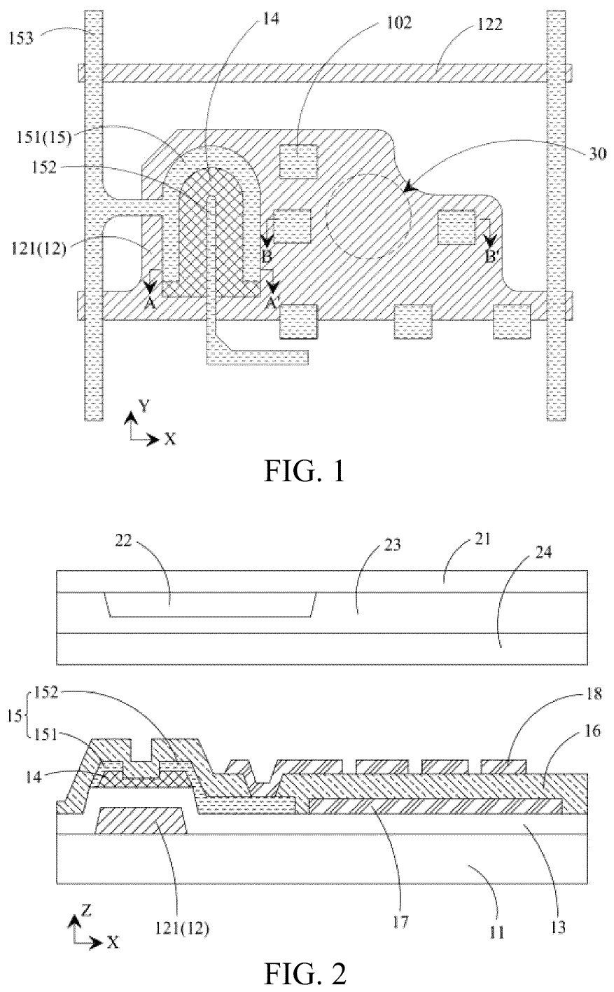

Referring to FIG. 1 and FIG. 2, FIG. 1 is a partial schematic view of a display panel according to a first embodiment of the present disclosure, and FIG. 2 is a sectional view of the display panel in the first embodiment along a direction A-A′ in FIG. 1, the display panel includes an array substrate 10 and an opposite substrate 20 arranged opposite to each other.

The display panel 100 is a liquid crystal display panel. The display panel further includes a liquid crystal layer (not shown in the figures) which is arranged between the array substrate 10 and the opposite substrate 20.

In an embodiment, the display panel 100 is a fringe field switching (FFS) liquid crystal display panel. In other embodiments, a type of the display panel 100 is not limited to the FFS liquid crystal display panel in the above embodiment, but can also be other existing types of liquid crystal display panels, and there is no unique limitation here.

As shown in FIG. 2, a plurality of spacers 30 are provided on a side of the opposite substrate 20 adjacent to the array substrate 10. An end of the spacer 30 is fixed on the opposite substrate 20, and another end of the spacer 30 abuts against a surface of the array substrate 10 adjacent to the opposite substrate 20.

The surface of the array substrate 10 adjacent to the opposite substrate 20 is provided with an alignment layer (not shown in the figures) thereon, and the alignment layer is provided with alignment grooves configured to make liquid crystal molecules in the liquid crystal layer have a pre-tilt angle. The end of the spacer 30 adjacent to the array substrate 10 is in direct contact with the alignment layer.

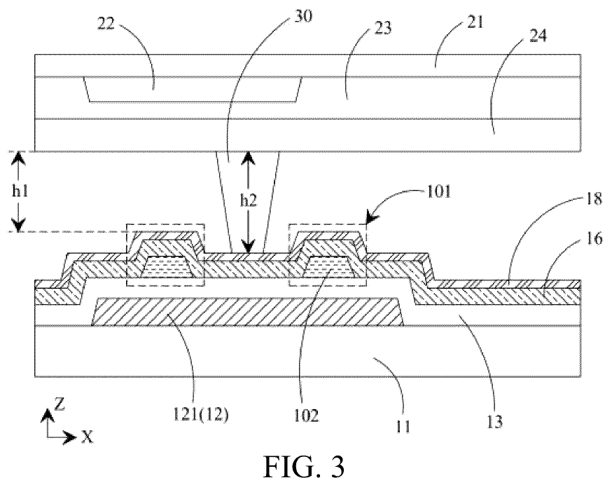

A shape of the spacer 30 may be a cylinder, a frustum, a prism, etc. In the embodiment shown in shown in FIG. 3, the shape of the spacer 30 is a circular frustum, and a cross-sectional shape of the spacer 30 is an inverted trapezoid. A diameter of the spacer 30 gradually decreases from the end adjacent to the opposite substrate 20 to the other end away from the opposite substrate 20.

In an embodiment, as shown in FIG. 2, the opposite substrate 20 is a color filter substrate, and the opposite substrate 20 may include a second base 21, a black matrix 22, a color filter layer 23, and a protection layer 24. The black matrix 22 and the color filter layer 23 are disposed on the second base 21, and the protection layer 24 is disposed on a side of the black matrix 22 and the color filter layer 23 away from the second base 21. The spacer 30 may be directly formed on a surface of the protection layer 24 away from the second base 21.

In an embodiment, the opposite substrate 20 may include the second base 21, the black matrix 22, and the protection layer 24, but not include the color filter layer 23 which may be arranged in the array substrate 10.

Referring to FIG. 1 and FIG. 3, FIG. 3 is a sectional view of the display panel in the first embodiment along a direction B-B′ in FIG. 1. A plurality of dams 101 are provided on the side of the array substrate 10 adjacent to the opposite substrate 20. The dams 101 are arranged around ends of the spacers 30 adjacent to the array substrate 10. The dams 101 can prevent the end of each of the spacers 30 adjacent to the array substrate 10 from sliding, so as to prevent the spacers 30 from scratching an alignment layer on a surface of the array substrate 10, thereby avoiding abnormal display problems of light leakage and red and blue spots on the display panel, and improving display effect of the display panel.

In an embodiment, each of the plurality of dams is arranged circumferentially along the end of the spacer adjacent to the array substrate and partially surrounds the spacer.

As shown in FIG. 1, a range indicated by a dotted circle in FIG. 1 is a range where the end of the spacer 30 adjacent to array substrate 10 abuts against the surface of the array substrate 10, and a periphery of the end of each spacer 30 adjacent to array substrate 10 is provided with multiple dams 101, which are distributed along a circumferential direction of the end of the spacer 30 adjacent to the array substrate 10. The multiple dams 101 can form a discontinuous ring structure, which partially surrounds the end of the spacer 30 adjacent to the array substrate 10. The spacer 30 is surrounded by the dams 101 by arranging the multiple dams 101 around the end of the spacer 30 adjacent to the array substrate 10, so as to limit the sliding of the spacer 30.

In an embodiment, the end of the spacer 30 adjacent to array substrate 10 can also be provided with only one dam 101, and the dam 101 is a closed circular structure to form a fully enclosed structure on the end of the spacer 30 adjacent to array substrate 10.

Furthermore, a minimum distance h1 between the dam 101 and the opposite substrate 20 is less than a height h2 of the spacer 30.

As shown in FIG. 3, the minimum distance h1 between the dam 101 and the opposite substrate 20 is a distance between an end of the dam 101 adjacent to the opposite substrate 20 and the opposite substrate 20 in a third direction Z, and the height h2 of the spacer 30 is a distance between the end of the spacer 30 adjacent to the array substrate 10 and the end of the spacer 30 adjacent to the opposite substrate 20 in the third direction Z. The end of the spacer 30 adjacent to the array substrate 10 can be ensured to come into contact with the dam 101 during sliding and be blocked by the dam 101 by making the minimum distance h1 between the dam 101 and the opposite substrate 20 less than the height h2 of the spacer 30.

Furthermore, the array substrate 10 includes a first base 11, buffer blocks 102, and inorganic insulation layer 16. The inorganic insulation layer 16 is arranged on the first base 11, and the buffer blocks 102 are arranged between the first base 11 and the inorganic insulation layer 16. The dam 101 is at least composed of the buffer block 102 and the inorganic insulation layer 16 located on the buffer block 102.

It should be noted that the inorganic insulation layer 16 is disposed on the first base 11 means that the inorganic insulation layer 16 is located on the first base 11, and the inorganic insulation layer 16 and the first base 11 are separated by other metal layers and/or insulation layers therebetween.

Referring to FIG. 1 and FIG. 2, the array substrate 10 further includes a first metal layer 12 and a second metal layer 15. The first metal layer 12 is disposed between the second metal layer 15 and the first base 11, and the first metal layer 12 may include a plurality of patterned gates 121 and a plurality of scan lines 122 extending along a first direction X. The second metal layer 15 may include a plurality of patterned sources 151 and the drains 152, and a plurality of data lines 153 extending along a second direction Y.

The array substrate 10 further includes a gate insulation layer 13 and an active layer 14. The first metal layer 12 is disposed on the first base 11, and the gate insulation layer 13 is disposed on the first base 11 and the first metal layer 12.

It should be noted that the first metal layer 12 is disposed on the first base 11, which may mean that the first metal layer 12 is located on the first base 11 and is in direct contact with a surface of the first base 11; or may refer to that the first metal layer 12 is located on the first base 11 and is separated from the first base 11 by a buffer layer and/or a barrier layer.

In the embodiment shown in FIG. 2, the first metal layer 12 is located on the first base 11 and is in direct contact with a surface of the first base 11 adjacent to the opposite substrate. The active layer 14 is disposed on a surface of the gate insulation layer 13 away from the first metal layer 12 and overlaps with the gates 121 in the first metal layer 12 in a direction perpendicular to the first base 11. The second metal layer 15 is disposed on the gate insulation layer 13 and the active layer 14, and the source 151 and the drain 152 are respectively overlapped on corresponding ohmic contacts in the active layer 14.

It should be noted that the direction perpendicular to the first base 11 refers to the third direction Z as shown in FIG. 2, which is perpendicular to the first direction X and the second direction Y.

In an embodiment, the buffer block 102 is arranged in a same layer as the second metal layer 15, is independent and not connected to the source and the drain.

Referring to FIG. 2 and FIG. 3, the buffer block 102 and the second metal layer 15 are both arranged on the gate insulation layer 13. The buffer block 102 and the second metal layer 15 may be made through a same metal film forming process. An electrical property of the buffer block 102 is an open circuit, and the buffer block 102 is not electrically connected to the source, the drain, or the data line in the second metal layer 15, nor is it connected to any other electrical signals.

The inorganic insulation layer 16 is disposed on the gate insulation layer 13 and covers the buffer blocks 102, the second metal layer 15, and the active layer 14. In the embodiment, the inorganic insulation layer 16 may also be referred to as a passive protection layer.

Specifically, a material of the inorganic insulation layer 16 may include but not limited to an inorganic transparent insulation material such as silicon nitride, silicon oxide, silicon oxynitride, and so on. The inorganic insulation layer 16 may be a single layer structure formed by any one of the inorganic transparent insulation materials of silicon nitride, silicon oxide, or silicon oxynitride, or may be a double-layer or multi-layer structure formed by any two or more inorganic transparent insulation materials of silicon nitride, silicon oxide, or silicon oxynitride.

Furthermore, the array substrate 10 further includes a first electrode layer 17 and a second electrode layer 18. The first electrode layer 17 is disposed on a surface of the gate insulation layer 13 away from the first base 11, and the second electrode layer 18 is disposed on a surface of the inorganic insulation layer 16 away from the first base 11, and is disposed on the second electrode layer 18 and a surface of the inorganic insulation layer 16 away from first base 11.

The first electrode layer 17 may include multiple patterned common electrodes, and the second electrode layer 18 may include multiple patterned pixel electrodes. In the direction perpendicular to the first base 11, the pixel electrode overlaps with the common electrode. When the display panel displays images, the pixel electrode and the common electrode can receive different electrical signals to form an electric field that drives a deflection of the liquid crystal molecules.

Specifically, a material of the first electrode layer 17 and a material of the second electrode layer 18 are both transparent conductive oxides, which can be, but are not limited to, indium tin oxide (ITO) or other transparent conductive metal oxide materials.

Referring to FIG. 3, it should be noted that the buffer block 102 has a certain thickness. After depositing to form the inorganic insulation layer 16, the buffer block 102 forms the dam 101 together with the inorganic insulation layer 16 and the second electrode layer 18 located on the buffer block 102. A segment difference can be formed between the dam 1011 and the inorganic insulation layer 16 without the buffer block 102 and the second metal layer 15 below, and a top of the dam 101 protrudes from an upper surface of the inorganic insulation layer 16 without the buffer block 102 and the second metal layer 15 below. Due to a thin thickness of the second electrode layer 18 and a thin thickness of the alignment layer, when the second electrode layer 18 and the alignment layer are formed during subsequent deposition, the second electrode layer 18 and the alignment layer cannot fill the segment differences formed by the dams, and the area where the dam is located can still protrude from other areas without the buffer block. Under this structure, the dam can block the sliding of the spacer 30, thereby preventing the spacer 30 from scratching the alignment layer on the surface of the array substrate 10.

In an embodiment, the thickness of the buffer block 102 is 0.5 μm. The top of the dam 101 protrudes from other surrounding areas at a height ranging from 0.2 μm to 0.9 μm. In practical applications, the thickness of the buffer block 102 may be set according to actual needs, not limited to 0.5 μm in the above embodiments. The thickness of the buffer block 102 can be same as a thickness of the second metal layer 15.

Furthermore, in the direction perpendicular to the first base 11, the buffer block 102 overlaps with the first metal layer 12, and the spacer 30 overlaps with the first metal layer 12.

Referring to FIG. 1 and FIG. 3, the first metal layer 12 includes patterned gates 121, which not only overlaps with the active layer 14 in the direction perpendicular to the first base 11, but also overlaps with the buffer block and the spacer 30, respectively.

It should be noted that by setting the buffer block above the gate 121 and overlapping the spacer 30 with the gate 121, not only can the distance between the buffer block 102 and the first base 11 be increased, but also the distance between the buffer block 102 and the opposite substrate 20 be reduced. It can also avoid setting the buffer block and the spacer 30 in other areas, which can reduce a pixel opening rate and lead to a decrease in a transmission rate of the display panel, so as to ensure the transmittance of the display panel while prevent the spacer 30 from scratching the alignment layer on the surface of the array substrate 10.

In other embodiments, the first metal layer 12 may further include other metal patterned structures other than the gates 121. The metal patterned structure may be independent of and not connected to the gate 121 or a gate line, or may be connected to the gate 121 or the gate line, and there is no unique limitation here. In the direction perpendicular to the first base 11, the buffer block 102 may overlap with the metal patterned structure, and the spacer 30 may also overlap with the metal patterned structure. This can also reduce the distance between the buffer block 102 and the opposite substrate 20.

Furthermore, in the direction perpendicular to the first base 11, the spacer 30 does not overlap with the second metal layer 15, and the spacer 30 does not overlap with the buffer block 102.

Referring to FIG. 1 and FIG. 3, only the gates 121 of the first metal layer 12 are arranged in an area corresponding to the spacers 30 on the array substrate 10, while the second metal layer 15 is not provided with a metal pattern in the area corresponding to the spacers 30. The buffer blocks are surrounded by the area corresponding to the spacers 30 to limit the sliding of the ends of the spacers 30 adjacent to the array substrate 10.

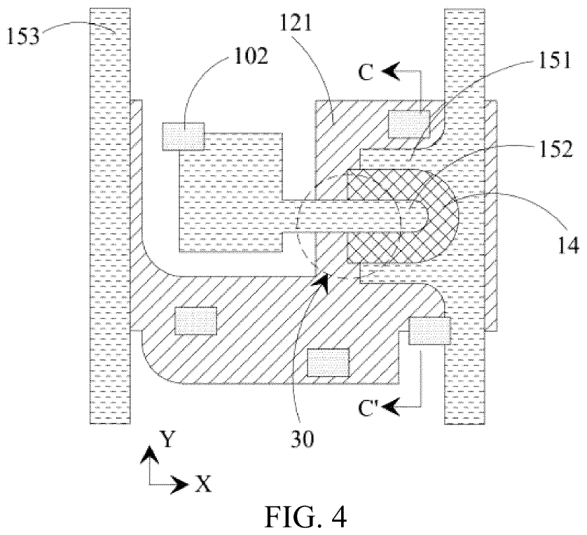

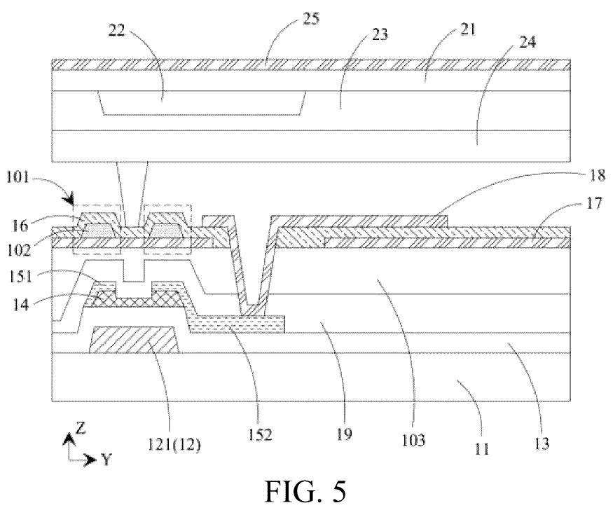

Referring to FIG. 4 and FIG. 5, FIG. 4 is a partial schematic view of a display panel according to a second embodiment of the present disclosure, and FIG. 5 is a sectional view of the display panel in the second embodiment along a direction C-C′ in FIG. 4. A structure of the display panel shown in FIG. 4 and FIG. 5 roughly same as that of the display panels shown in FIG. 1 to FIG. 3, except that the buffer block is not arranged in a same layer as the second metal layer 15, but on a side of the second metal layer 15 away from the first base 11.

Furthermore, the array substrate 10 further includes a planarization layer 103, which is located on the side of the second metal layer 15 away from the first base 11. The buffer blocks 102 are located on a side of the planarization layer 103 away from the first base 11. The planarization layer 103 is made of organic resin, preferably PFA plastic.

As illustrated in FIG. 5, the array substrate 10 further includes a first passivation layer 19, which is arranged on the gate insulation layer 13 and covers the second metal layer 15 and the active layer 14. The planarization layer 103 is disposed on the first passivation layer 19. The first electrode layer 17 is disposed on first passivation layer 19. The buffer block 102 is disposed on a side of the first electrode layer 17 away from the first base 11. The inorganic insulation layer 16 is disposed on the side of the first electrode layer 17 and a side of the buffer block 102 away from the first base 11. The second electrode layer 18 is disposed on the inorganic insulation layer 16, and the alignment layer is disposed on the second electrode layer 18 and the inorganic insulation layer 16.

In the embodiment illustrated in FIG. 5, the inorganic insulation layer 16 may also be referred to as a second passivation layer. The material and film structure of the inorganic insulation layer 16 are same as those of the inorganic insulation layer in the embodiments illustrated in FIG. 1 to FIG. 4, and will not be elaborated here.

Materials of the first passivation layer 19 and the gate insulation layer 13 may include, but are not limited to, inorganic transparent insulating materials such as silicon nitride, silicon oxide, silicon oxynitride, and so on. Each of the first passivation layer 19 and the gate insulation layer 13 may be a single-layer structure formed by any one of the inorganic transparent insulating materials of silicon nitride, silicon oxide, or silicon oxynitride, or may be a double-layer or multi-layer structure formed by any two or more inorganic transparent insulating materials of silicon nitride, silicon oxide, or silicon oxynitride.

It should be noted that in the embodiment shown in FIG. 5, the buffer block 102 is disposed on the side of the first electrode layer 17 away from the first base 11, which means that the buffer block 102 is located on the first electrode layer 17 and directly contacts the surface of the first electrode layer 17 away from the first base 11, and can serve as a common electrode together with a transparent electrode inside the first electrode layer 17. In other embodiments, the buffer block 102 is located on the first electrode layer 17 and is separated from the first electrode layer 17 by an insulation layer.

In the embodiment shown in FIG. 5, a segment difference between the first metal layer 12 and the second metal layer 15 is flattened by the planarization layer 103. By arranging the buffer blocks 102 on the side of the planarization layer 103 away from the first base 11, the buffer block 102 can form the dam with the inorganic insulation layer 16 formed on the buffer block 102, and the segment difference can be formed between the buffer block 102 and the surrounding inorganic insulation layer 16 without the buffer blocks. A subsequent formation of the second electrode layer 18 and the alignment layer cannot flatten the segment difference, and the dam can block the sliding of the spacer 30.

Beneficial effects of the embodiments of the present disclosure are: display panels and display devices are provided according to the embodiments of the present disclosure, the display panel includes the array substrate and the opposite substrate arranged opposite to each other, and a plurality of spacers are provided on a side of the array substrate adjacent to the opposite substrate. Since the plurality of dams are provided on the side of the array substrate adjacent to the opposite substrate, and the dams are arranged around ends of the spacers adjacent to the array substrate, the dams can prevent sliding of the ends of the spacers adjacent to the array substrate, thereby preventing the spacers from scratching the alignment layer on the surface of the array substrate, and thus avoiding abnormal display problems of light leakage and red and blue spots on the display panel.

According to the display panels provided in above embodiments of the present disclosure, the present disclosure further provides a display device, which includes but is not limited to a frame, a circuit board, a power supply, a camera, and the display panel. The circuit board, the power supply, and the camera may be installed inside the frame, and the display panel may be installed on the frame. The display panel can be any of the display panels provided in the above embodiments of the present disclosure. The structure of the display panel can refer to the above embodiments and will not be repeated here.

In the embodiment of the present disclosure, the display device may be, but is not limited to, a consumer electronic product such as a mobile phone, a smartwatch, a television, a tablet, a laptop, a desktop computer, a digital camera, and so on.

In summary, although the present disclosure has disclosed the above with preferred embodiments, but the above preferred embodiments are not intended to limit the present disclosure. For those skilled in the art, various modifications and modifications can be made without departing from the spirit and scope of the present disclosure, so the protection scope of the present disclosure is subject to the scope defined by the claims.

1. A display panel, comprising an array substrate and an opposite substrate arranged opposite to each other,
wherein a plurality of spacers are provided on a side of the opposite substrate adjacent to the array substrate, a plurality of dams are provided on a side of the array substrate adjacent to the opposite substrate, and the dams are arranged around ends of the spacers adjacent to the array substrate.

2. The display panel according to claim 1, wherein the dams are distributed along circumferential directions of the ends of the spacers adjacent to the array substrate and partially surround each of the spacers.

3. The display panel according to claim 1, wherein a minimum distance between each of the dams and the opposite substrate is less than a height of each of the spacers.

4. The display panel according to claim 1, wherein the array substrate comprises a first base, an inorganic insulation layer, and buffer blocks disposed between the first base and the inorganic insulation layer, and each of the dams is composed of one of the buffer blocks and the inorganic insulation layer located on the one of the buffer blocks.

5. The display panel according to claim 4, wherein the array substrate comprises a first metal layer and a second metal layer, the first metal layer is disposed between the second metal layer and the first base, the first metal layer comprises gates, and the second metal layer comprises sources and drains; and
wherein the buffer blocks are arranged in a same layer as the second metal layer and independently separated from the sources and the drains.

6. The display panel according to claim 5, wherein in a direction perpendicular to the first base, each of the buffer blocks partially overlaps with the first metal layer, and each of the spacers overlaps with the first metal layer.

7. The display panel according to claim 6, wherein in the direction perpendicular to the first base, each of the spacers does not overlap with the second metal layer, and each of the spacers does not overlap with the buffer blocks.

8. The display panel according to claim 4, wherein the array substrate comprises a first metal layer and a second metal layer, the first metal layer is disposed between the second metal layer and the first base; the first metal layer comprises gates, and the second metal layer comprises sources and drains; and
wherein the buffer blocks are arranged on a side of the second metal layer away from the first base.

9. The display panel according to claim 8, wherein the array substrate comprises a planarization layer disposed on the side of the second metal layer away from the first base, and the buffer blocks are disposed on a side of the planarization layer away from the first base.

10. The display panel according to claim 4, wherein an orthographic projection of each of the buffer blocks on the first base is shaped as a rectangle, a square, a circle, or an oval.

11. A display device, comprising a display panel comprising an array substrate and an opposite substrate arranged opposite to each other,
wherein a plurality of spacers are provided on a side of the opposite substrate adjacent to the array substrate, a plurality of dams are provided on a side of the array substrate adjacent to the opposite substrate, and the dams are arranged around ends of the spacers adjacent to the array substrate.

12. The display device according to claim 11, wherein the dams are distributed along circumferential directions of the ends of the spacers adjacent to the array substrate and partially surround each of the spacers.

13. The display device according to claim 11, wherein a minimum distance between each of the dams and the opposite substrate is less than a height of each of the spacers.

14. The display device according to claim 1, wherein the array substrate comprises a first base, an inorganic insulation layer, and buffer blocks disposed between the first base and the inorganic insulation layer, and each of the dams is composed of one of the buffer blocks and the inorganic insulation layer located on the one of the buffer blocks.

15. The display device according to claim 14, wherein the array substrate comprises a first metal layer and a second metal layer, the first metal layer is disposed between the second metal layer and the first base, the first metal layer comprises gates, and the second metal layer comprises sources and drains; and
wherein the buffer blocks are arranged in a same layer as the second metal layer and independently separated from the sources and the drains.

16. The display device according to claim 15, wherein in a direction perpendicular to the first base, each of the buffer blocks partially overlaps with the first metal layer, and each of the spacers overlaps with the first metal layer.

17. The display device according to claim 16, wherein in the direction perpendicular to the first base, each of the spacers does not overlap with the second metal layer, and each of the spacers does not overlap with the buffer blocks.

18. The display device according to claim 14, wherein the array substrate comprises a first metal layer and a second metal layer, the first metal layer is disposed between the second metal layer and the first base, the first metal layer comprises gates, and the second metal layer comprises sources and drains; and
wherein the buffer blocks are arranged on a side of the second metal layer away from the first base.

19. The display device according to claim 18, wherein the array substrate comprises a planarization layer disposed on the side of the second metal layer away from the first base, and the buffer blocks are disposed on a side of the planarization layer away from the first base.

20. The display device according to claim 14, wherein an orthographic projection of each of the buffer blocks on the first base is shaped as a rectangle, a square, a circle, or an oval.
